(19) United States
(12) Patent Application Publication
(10) Pub. No.: US 2002/0033496 A1
(43) Pub. Date: Mar. 21, 2002

(54) Semiconductor device and fabrication method of the same

(76) Inventor: Ryuji Nakajima, Tokyo (JP)

Correspondence Address: Darryl G. Walker, WALKER & SAKO, LLP, Suite 235, 300 South First Street, San Jose, CA, 95113, US

(21) Appl. No.: 09/955,718

(22) Filed: Sep. 19, 2001

(30) Foreign Application Priority Data
Sep. 20, 2000 (JP) 2000-285492

(51) Int. Cl. H01L 27/108; H01L 29/76; H01L 29/94; H01L 31/119

(52) U.S. Cl. 257/303

(57) ABSTRACT

A semiconductor device is disclosed including a capacitor electrode (4) comprised of conductor layers (4a, 4b, and 4c) formed on a semiconductor substrate. The capacitor electrode (4) may be cylindrical and may include an inner wall on the surface of conductor layer (4a) and an outer wall on the surface of conductor layer (4c). Conductor layer (4b) may be a central layer and may have a higher impurity concentration than conductor layers (4a and 4c). Hemi-spherical grains (5a) formed on the inner wall may be larger than hemi-spherical grains (5b) formed on the outer wall. The surface area of the capacitor electrode may be increased thereby providing a higher capacitance value.

### TECHNICAL FIELD

The present invention relates generally to a semiconductor device and fabrication method of the same, and more specifically to a semiconductor device including a cylindrical electrode having a large surface area providing a large capacitance.

### BACKGROUND OF THE INVENTION

In a semiconductor device such as a dynamic random access memory, it is desired to provide a memory cell having a large capacitance value without occupying a large amount of chip area. One method of providing a relatively large capacitance value is with a vertically disposed cylindrical capacitor.

Conventional cylindrical capacitor electrode formation processes will now be described with reference to FIGS. 3 to 10.

Referring now to FIGS. 3 to 10, cross-sectional diagrams of a conventional semiconductor device after various processing steps for forming a cylindrical capacitor electrode is set forth.

As illustrated in FIG. 3, an interlayer film 1 is formed on a semiconductor substrate (not shown). Interlayer film 1 serves as an insulating film. A contact plug 2 is provided in an opening portion in interlayer insulating film 1. The contact plug 2 is composed of a conductor layer and reaches the semiconductor substrate. A cylinder core film 3 is then formed on the interlayer film 1 and the contact plug 2.

Referring now to FIG. 4, a cylinder opening portion is then formed in cylinder core film 3 with a photolithography process such that contact plug 2 is exposed. The interlayer film 1 can be a single layer film having selectivity in etching with respect to the cylinder core film 3.

Referring now to FIG. 5, a conductor layer 4 may then be deposited over the surface including the contact plug.

Referring now to FIG. 6, the surface of the conductor layer 4 is then etched back with an anisotropic etch until the core film 3 is exposed. Conductor layer 4 forms a cylindrical electrode of a cell capacitor 4′.

Referring now to FIG. 7, a HSG (Hemi-Spherical-Grain) 5 structure is then formed on the surface of the capacitor electrode. The HSG 5 increases the surface area of the capacitor electrode and thus increases the capacitance value. In this way, memory cell capacitance can be increased without increasing the size of the memory cell capacitor. HSG 5 are hemis-spherical grains formed on the electrode surface using a CVD (chemical vapor deposition) process.

Cylindrical electrode 4′ is formed so that both the inner wall portion and the outer wall portion provide surface area for a cell capacitor electrode. After the inner wall portion of the cylindrical electrode 4′ is formed with the HSG 5 structure, the cylinder core film 3 is removed using a dry etch under conditions where a selection ratio for the interlayer film 1 is secured. Alternatively, a wet etch with a chemical solution may be performed. The result is illustrated in FIG. 8. In this way, a cylindrical electrode 4′ is formed having HSG 5 on an inner wall to increase capacitance value.

However, to further increase capacitance value, after the outer wall portion of the cylindrical electrode 4′ is exposed, so that an HSG structure can be formed on both the inner and outer wall portions in order to further increase capacitance.

FIG. 9 is a cross-section illustrating a case in which both the inner and outer wall portions of the cylindrical electrode 4′ is exposed before providing the HSG process.

Referring now to FIG. 10, HSG 5 is formed on the surface of cylindrical electrode 4′ using a CVD process. In this way, the surface area on both the inner wall and outer wall of the cylindrical electrode 4′ is increased. Thus the memory cell capacitance is even further increased without increasing the memory cell size with respect to the case illustrated in FIG. 8.

Japanese Laid-Open Patent Publication No. 2000-164828 (JPA-164828) illustrates a method of forming a cylindrical electrode and will be described with reference to FIGS. 12(a)-12(e).

Referring now to FIGS. 12(a)-12(e), cross-sectional diagrams of a conventional semiconductor device after various processing steps for forming a cylindrical capacitor electrode is set forth.

As illustrated in FIG. 12(a), an insulating film 104 is formed on a semiconductor substrate 103. A contact opening 105 is then formed in the insulating film 104. The contact opening reaches the surface of the semiconductor substrate 103. A first DOPOS (Doped-Poly-Silicon) film 106a is formed on the surface. First DOPOS film 106a has a thickness of about 400 Angstroms and constitutes a first stack electrode. First DOPOS film 106a includes phosphorus impurity at a concentration of 1.5×10²⁰ cm⁻³ or more and is formed within a temperature range of 530° C. to 550° C.

A second DOPOS film 108a is then formed on the first DOPOS film 106a. Second DOPOS film 108a has a thickness of about 400 Angstroms and constitutes a second stack electrode. Second DOPOS film 108a has a phosphorus impurity concentration lower than first DOPOS film 106a. Second DOPOS film 108a includes phosphorus impurity at a concentration of 5×10¹⁹ cm⁻³ to 1.5×10²⁰ cm⁻³ and is formed within a temperature range of 530° C. to 550° C.

In this way, first and second DOPOS films (106a and 108a) are a laminate film 110 in which there is higher phosphorus concentration on the outside and a lower phosphorus concentration on the inside.

Referring now to FIG. 12(b), the entire surface of semiconductor substrate 103 is heated at a temperature of 500° C. or lower to form a silicon oxide film 111. In this way, contact hole 105 is filled with SiO₂.

Referring now to FIG. 12(c), silicon oxide film 111, first DOPOS film 106a, and second DOPOS film 108a are then etched back.

Referring now to FIG. 12(d), insulating film 104 and silicon oxide film 111 are removed by wet etching using an HF solution, for example, to form cylindrical stack 112 composed of laminate film 110 (first and second DOPOS films 106a and 108a).

Referring now to FIG. 12(e), cylindrical stack 112 is then exposed to SiH₄ or Si₂H₆ in high vacuum and is heat treated in a temperature range of 550° C. to 580° C., for example, in high vacuum. In this way, high-density first and second HSG (hemi-spherical-grained) nuclei (107 and 109) are grown on the inner wall and outer wall of cylindrical stack 112.

Because the phosphorus concentration in second DOPOS film 108a on the inner wall of stack electrode 102 is lower than the phosphorus concentration in first DOPOS film 106a on the outer wall of stack electrode 102, the grain size of second HSG 109 larger than the grain size of first HSG 107. The grain size of second HSG 109 is about 500 to 1000 Angstroms.

The grain size of first HSG 107 on the outer wall is smaller than that of second HSG 109 on the inner wall. Thus exfoliation of first HSG 107 may be reduced and outer walls of adjacent stack electrodes may be prevented from being shorted due to contact between respective HSGs.

As discussed earlier, it is possible to increase memory cell capacitance by constructing the inner and outer walls of a capacitor electrode as an HSG structure. It is noted that the larger the grain size of the HSG, the larger the capacitance value may become.

Referring now to FIG. 11, a schematic diagram illustrating a relationship between contact width and HSG grain size is set forth. A grain of HSG can have a surface contacting the conductor layer. As the grain size of the HSG increases, the contact width with the conductor layer is likely to be reduced as illustrated in FIG. 11. This can decrease the ability for the HSG to withstand any shocks or stress. Accordingly, when any shock is exerted on the cell in a later processing step (ultrasonic cleaning, etc.), the grains are more likely to be exfoliated if the grain size is larger.

The grains are conductors and occurrence of exfoliation may cause grains to adhere between adjacent cylindrical capacitor electrodes. This may create a shorting path between adjacent capacitors, which can decrease chip yields and increase manufacturing costs. This can be problematic when the outer walls of cylindrical capacitor electrodes are used to provide surface area in the cell capacitor.

In light of the above discussion, it would be desirable to provide a semiconductor device including a capacitor having a cylindrical electrode with a large surface area so that a large capacitance value can be achieved.

### SUMMARY OF THE INVENTION

A semiconductor device according to the present embodiments may include a capacitor electrode comprised of three conductor layers. The capacitor electrode may be cylindrical and may include an inner wall surface and an outer wall surface. A central conductor layer may have a higher impurity concentration than outer conductor layers. Hemi-spherical grains formed on the inner wall may be larger than hemi-spherical grains formed on the outer wall. The surface area of the capacitor electrode may be increased thereby providing a higher capacitance value.

According to one aspect of the embodiments, a semiconductor device may include a capacitor electrode including an inner wall conductor layer, a central conductor layer, and an outer wall conductor layer. A first impurity concentration in the central layer may be higher than the first impurity concentration in the inner wall conductor layer.

According to another aspect of the embodiments, the first impurity concentration in the central conductor layer may be higher than the first impurity concentration in the outer wall conductor layer.

According to another aspect of the embodiments, first grain structures may be formed on the surface of the inner wall conductor layer. Second grain structures may be formed on the surface of the outer wall conductor layer. The first grain structures may be larger than the second grain structures.

According to another aspect of the embodiments, the capacitor electrode may be cylindrical.

According to another aspect of the embodiments, the film thickness of the inner wall conductor layer may be greater than the film thickness of the outer wall conductor layer.

According to another aspect of the embodiments, the first impurity concentration of the outer wall conductor layer may be equal to the first impurity concentration of the inner wall conductor layer.

According to another aspect of the embodiments, the first impurity may be phosphorus.

According to another aspect of the embodiments, a method of fabricating a semiconductor device including a capacitor electrode may include the steps of: forming an insulating film on a semiconductor substrate, forming an opening portion in the insulating film, forming a first conductor layer within the opening portion, forming a second conductor layer on the first conductor layer, and forming a third conductor layer on the second conductor layer. The capacitor electrode may include the first conductor layer, second conductor layer, and third conductor layer and hemispherical grains may be formed on a surface of the capacitor electrode.

According to another aspect of the embodiments, forming the opening portion may include forming the opening portion at a position where a capacitor contact is provided.

According to another aspect of the embodiments, the first conductor layer may have a first impurity concentration that is lower than the first impurity concentration of the second conductor layer. The first impurity concentration of the third conductor layer may be lower than the first impurity concentration of the second conductor layer.

According to another aspect of the embodiments, The first impurity concentration of the first conductor layer may be equal to the first impurity concentration of the third conductor layer.

According to another aspect of the embodiments, forming hemispherical grains on the surface of the capacitor electrode may include a chemical vapor deposition step.

According to another aspect of the embodiments, the capacitor electrode may be cylindrical and may have an inner surface and an outer surface. The hemi-spherical grains formed on the inner surface may be larger than the hemi-spherical grains formed on the outer surface.

According to another aspect of the embodiments, a capacitor electrode may include a first external conductor layer, a central conductor layer, and a second external conductor layer. First grain structures formed on the first external conductor layer may be larger than second grain structures formed on the second external conductor layer.

According to another aspect of the embodiments, a first impurity concentration in the central conductor layer may be higher than the first impurity concentration in the first external conductor layer.

According to another aspect of the embodiments, the first external conductor layer second external conductor layer, and central conductor layer may be comprised of doped poly-silicon.

According to another aspect of the embodiments, the first grain structures may be formed on an inner surface of the capacitor electrode. The second grain structures may be formed on an outer surface of the capacitor electrode.

According to another aspect of the embodiments, the capacitor electrode may be cylindrical.

According to another aspect of the embodiments, the thickness of the first external conductor layer may be greater than the thickness of the second external conductor layer.

According to another aspect of the embodiments, the semiconductor device may be a dynamic random access memory and the capacitor electrode may store charge indicating a data value.

### BRIEF DESCRIPTION OF THE DRAWINGS

FIG. 1 is a cross-sectional diagram of a portion of a semiconductor device after various processing steps for forming a cylindrical capacitor electrode according to one embodiment.

FIG. 2 is a cross-sectional diagram of a portion of a semiconductor device illustrating the construction of a conductor layer used for the cylindrical electrode according to one embodiment.

FIG. 3 is a cross-sectional diagram of a conventional semiconductor device after various processing steps for forming a cylindrical capacitor electrode.

FIG. 4 is a cross-sectional diagram of a conventional semiconductor device after various processing steps for forming a cylindrical capacitor electrode.

FIG. 5 is a cross-sectional diagram of a conventional semiconductor device after various processing steps for forming a cylindrical capacitor electrode.

FIG. 6 is a cross-sectional diagram of a conventional semiconductor device after various processing steps for forming a cylindrical capacitor electrode.

FIG. 7 a cross-sectional diagram of a conventional semiconductor device after various processing steps for forming a cylindrical capacitor electrode.

FIG. 8 is a cross-sectional diagram of a conventional semiconductor device after various processing steps for forming a cylindrical capacitor electrode.

FIG. 9 a cross-sectional diagram of a conventional semiconductor device after various processing steps for forming a cylindrical capacitor electrode.

FIG. 10 a cross-sectional diagram of a conventional semiconductor device after various processing steps for forming a cylindrical capacitor electrode.

FIG. 11 is a schematic diagram illustrating a relationship between contact width and HSG grain size.

FIGS. 12(a)-12(e) are cross-sectional diagrams of a conventional semiconductor device after various processing steps for forming a cylindrical capacitor electrode.

### DETAILED DESCRIPTION OF THE EMBODIMENTS

Various embodiments of the present invention will now be described in detail with reference to a number of drawings.

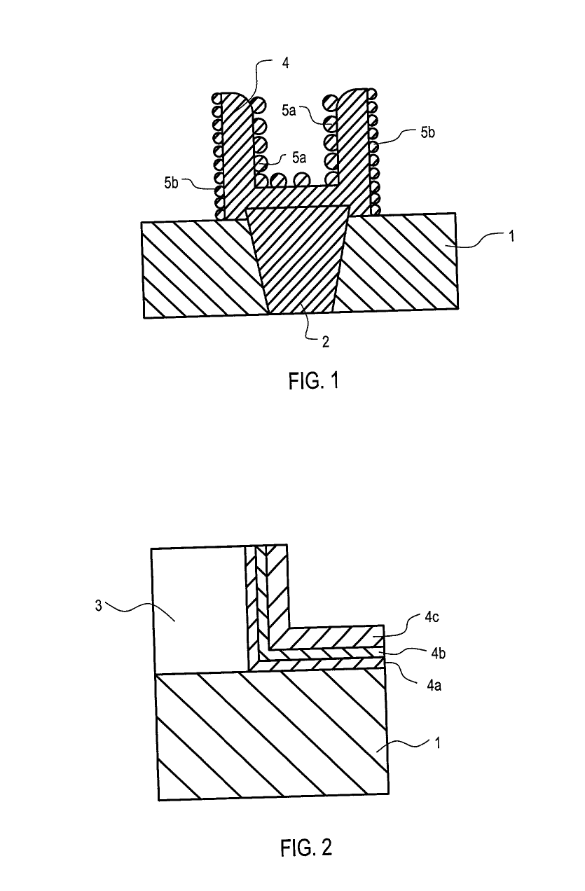

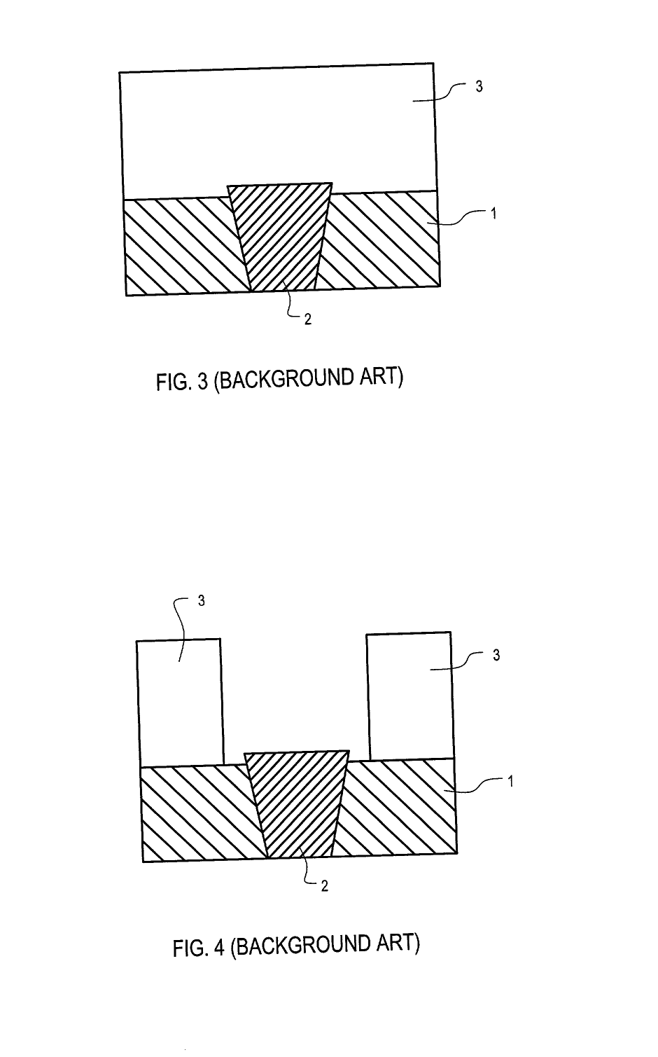

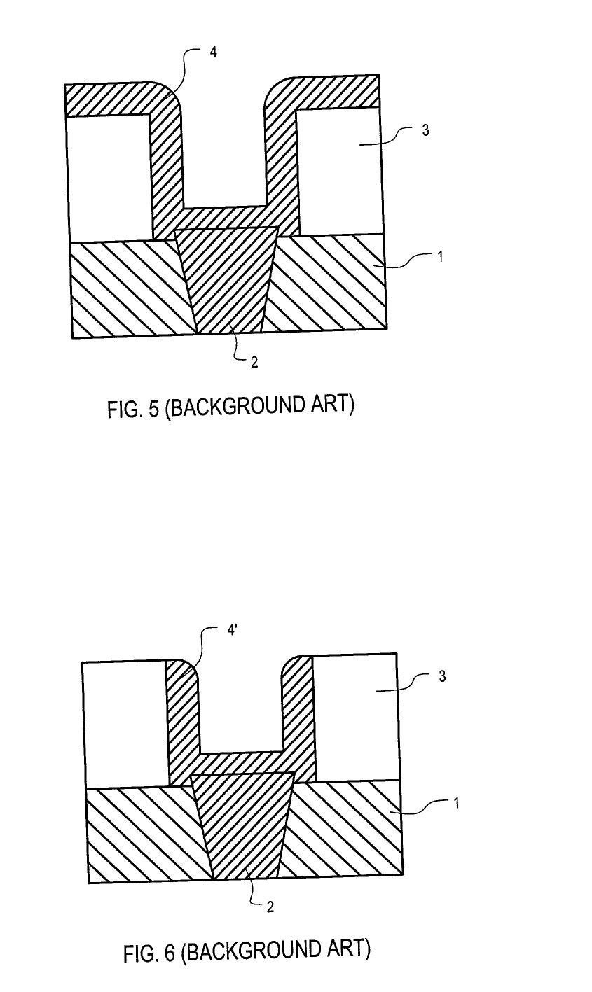

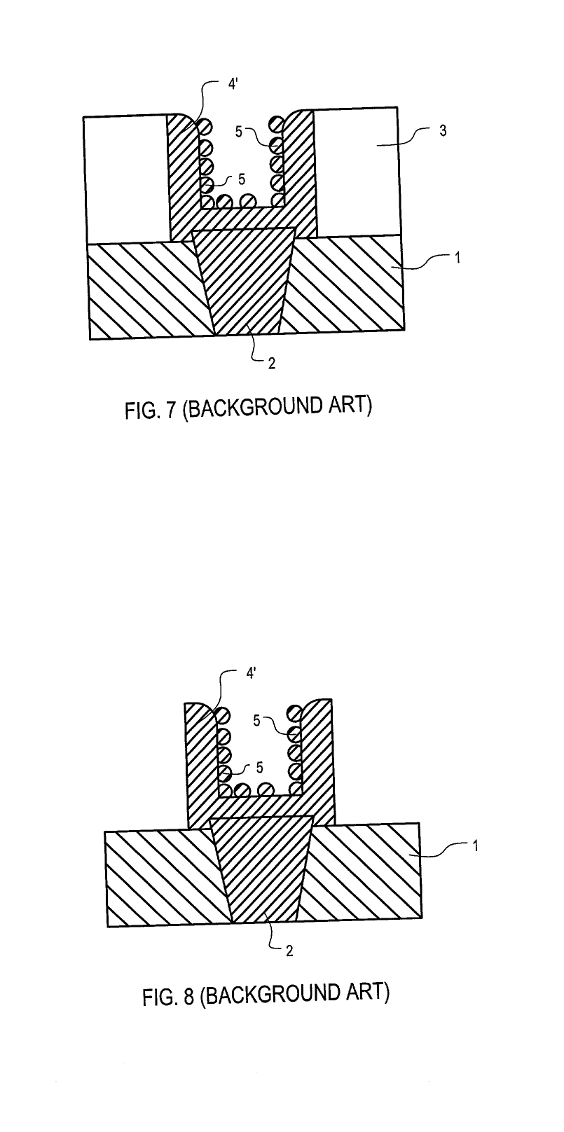

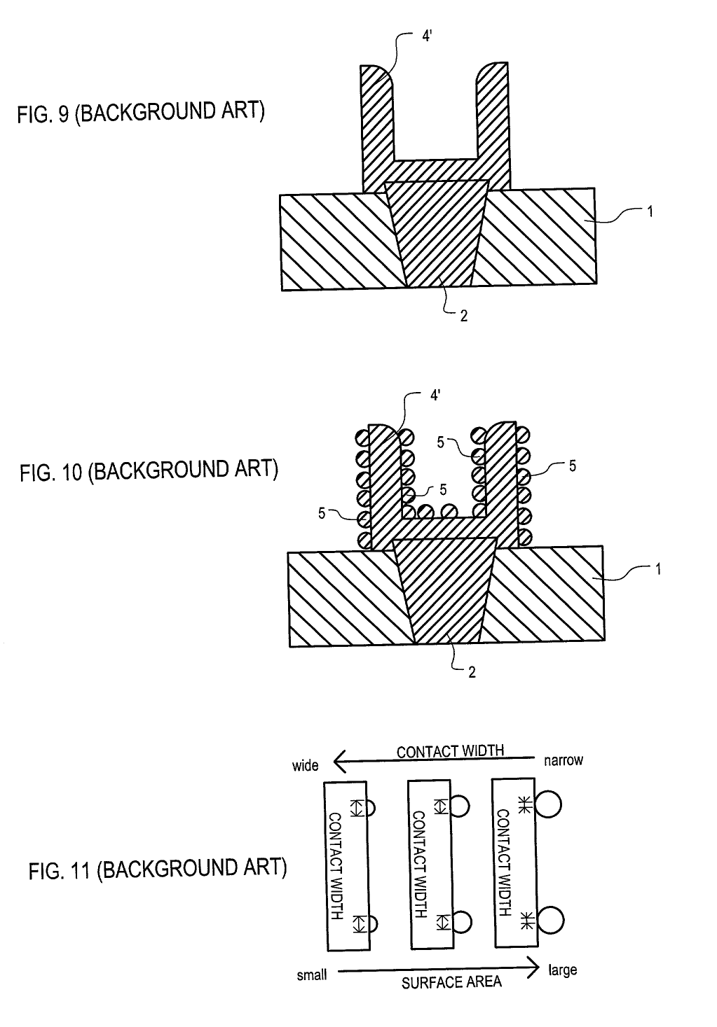

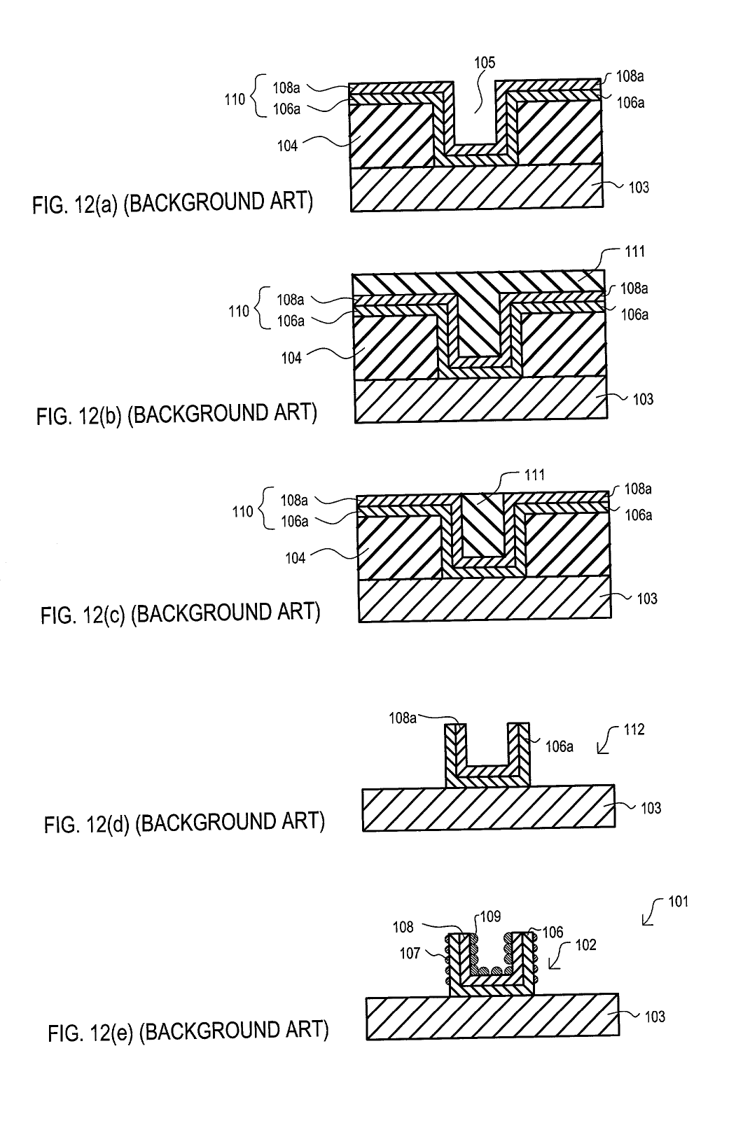

Referring now to FIG. 1, a cross-sectional diagram of a portion of a semiconductor device after various processing steps for forming a cylindrical capacitor electrode according to one embodiment is set forth.

The semiconductor device of FIG. 1 may include a contact plug 2 formed in an interlayer film 1. A cylindrical electrode 4 may be formed on the contact plug and portions of interlayer film 1 and may be in electrical contact with the contact plug 2.

As illustrated in FIG. 1, cylindrical electrode 4 may have a HSG (hemi-spherical grain) structure 5b on the outer wall may have a smaller grain size than a HSG structure 5a on the inner wall.

Referring now to FIG. 2, a cross-sectional diagram of a portion of a semiconductor device illustrating the construction of a conductor layer used for the cylindrical electrode 4 in FIG. 1.

As illustrated in FIG. 2, a conductor layer that may be used for cylindrical electrode 4 in FIG. 1, may be a three-layered structure. In this way HSG grain sizes may be different between the inner wall and outer wall of cylindrical electrode 4.

As illustrated in FIG. 2 in conjunction with FIG. 1, interlayer film 1 may be formed on a semiconductor substrate (not shown). The interlayer film 1 may serve as an insulating film. A contact plug 2 (not shown in FIG. 2) may be formed in an opening portion of the interlayer film 1. The contact plug may reach the semiconductor substrate and may provide an electrical connection between a memory cell capacitor electrode and memory cell transistor in a DRAM (dynamic random access memory). The memory cell capacitor electrode may be for storing charge indicating a data value stored in the particular memory cell.

A cylindrical core film 3 may be formed on the interlayer insulating film 1 and contact plug 2. A cylinder opening portion may be formed with a photolithography process in the cylinder core film 3 exposing the upper surface of the contact plug 2. Then, a conductor composed of conductor layers (4a, 4b, and 4c) may be formed. Conductor layers (4a, 4b, and 4c) may be used to form cylindrical electrode 4 which may be a memory cell capacitor electrode.

The three-layer conductor including conductor layers (4a, 4b, and 4c) may include a conductor layer 4b that may be a high concentration layer where no HSG may be formed. The high concentration layer 4b may be disposed in a central portion of the three-layered conductor. Conductor layers (4a and 4c) may be relatively low concentration layers where the HSG can be grown and may be disposed on both sides of conductor layer 4b. Conductor layer 4a that provides the outer wall of cylindrical electrode 4 may be thinner than conductor layer 4c that provides the inner wall of cylindrical electrode 4. After the HSG processing, the grain size may be larger on the inner wall side of cylindrical electrode 4 than on the outer wall side of cylindrical electrode 4. As illustrated in FIG. 1, inner wall HSG 5a grain size may be larger than outer wall HSG 5b grain size.

Grain sizes of HSGs (5a and 5b) may be different depending on whether they are located on the inner wall or outer wall of cylindrical electrode 4. Generally, the surface area can be increased as the grain size of HSG is larger. However, as grain size becomes larger exfoliation may be increased. So, the inner wall portion HSG 5a may have a relatively large grain size with respect to outer wall portion HSG 5b. In this way, capacitance value may be high and short-circuiting between adjacent cylindrical electrodes may be reduced.

In the present embodiment, conductor layers (5a, 5b, and 5c) may be made of Doped-Poly-Silicon (DOPOS), as just one example. DOPOS may be used because lower concentration doped DOPOS may form hemi-spherical grains (HSG) in a heat treatment in high vacuum, while higher concentration doped DOPOS may not have growth of HSG under the same conditions. In this way, HSG may be selectively formed.

As disclosed in the above embodiments, a semiconductor device may include a capacitor having a cylindrical electrode. The cylindrical electrode may be formed on a semiconductor substrate and may include a three-layered conductor. The size of grains formed on the inner wall side of the cylindrical electrode may be greater than the size of grains formed on the outer wall side of the cylindrical electrode. Impurity concentrations of a central layer among the three conductor layers may be higher than the impurity concentration of the opposite side layers. Grains may be grown on the inner wall side and outer wall side of the cylindrical electrode and may increase surface area of the electrode. In this way, a capacitance value of a capacitor including the cylindrical electrode may be increased without increasing the overall size of the capacitor structure.

The film thickness of an inner wall layer may be greater than the film thickness of the outer wall layer. In this way, grain sizes of grains grown on the inner wall may be larger than grain sizes of grains grown on the outer wall of the cylindrical electrode.

Grain sizes may differ between the inner wall and outer wall of the cylindrical electrode based on the thickness of the inner wall layer and outer wall layer even though the impurity concentrations of the inner wall layer an outer wall layer may be essentially equal.

A method of fabricating a semiconductor device including a cylindrical electrode is provided. The method may include the steps of forming an insulating film, forming a first conductor layer at an opening portion, forming a second conductor layer on the first conductor layer, forming a third conductor layer on the second conductor layer, and forming hemi-spherical grains on the surface of the electrode with a CVD method. The first conductor layer and third conductor layer may have a lower impurity concentration than the second conductor layer. The cylindrical electrode including the three conductor layers may be formed having a large surface area so that a capacitor including the cylindrical electrode may have an increased capacitance value without increasing area consumption.

The semiconductor device may include a cylindrical electrode having different grain sizes fabricated due to differences in thickness between opposite side layers among the three conductor layers. The inside conductor layer (third conductor layer) of the cylindrical electrode may be thicker than the outside conductor layer (first conductor layer) of the cylindrical electrode. The size of grains formed on the inside conductor layer may be larger than the size of grains formed on the outside conductor layer.

The semiconductor device may include a cylindrical electrode having different grain sizes on the inside and outside of the cylindrical electrode even though first and third conductor layers may have the same impurity concentrations.

The cylindrical electrode may be a storage electrode for data in a dynamic random access memory. A dielectric layer may be formed on the storage electrode. A plate structure may be formed on the dielectric layer and may provide a second electrode for a memory cell capacitor. The plate structure may be electrically connected to a bias potential. The storage electrode (cylindrical electrode) may be electrically connected to a memory cell transistor. The memory cell transistor may be an insulated gate field effect transistor (IGFET).

It is understood that the embodiments described above are exemplary and the present invention should not be limited to those embodiments. Specific structures should not be limited to the described embodiments.

It is understood that the present invention should not be limited to structural materials and conditions of film formation, etc. demonstrated in the embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a capacitor electrode including an inner wall conductor layer, a central conductor layer, and an outer wall conductor layer; and
a first concentration of a first impurity in the central conductor layer is higher than a second concentration of the first impurity in the inner wall conductor layer.

2. The semiconductor device according to claim 1, wherein:
the first concentration of the first impurity in the central conductor layer is higher than a third concentration of the first impurity in the outer wall conductor layer.

3. The semiconductor device of claim 1, further including:
first grain structures formed on the surface of the inner wall conductor layer;
second grain structures formed on the surface of the outer wall conductor layer; and
the first grain structures are larger than the second grain structures.

4. The semiconductor device of claim 1, wherein:
the capacitor electrode is cylindrical.

5. The semiconductor device of claim 1, wherein:
the film thickness of the inner wall conductor layer is greater than the film thickness of the outer wall conductor layer.

6. The semiconductor integrated circuit device of claim 1, wherein:
the third concentration of the first impurity in the outer wall conductor layer is essentially equal to the first concentration of the first impurity in the inner wall conductor layer.

7. The semiconductor integrated circuit device of claim 1, wherein:
the first impurity is phosphorus.

8. A method of fabricating a semiconductor device including a capacitor electrode, comprising the steps of:
forming an insulating film on a semiconductor substrate;
forming an opening portion in the insulating film;
forming a first conductor layer within the opening portion;
forming a second conductor layer on the first conductor layer;
forming a third conductor layer on the second conductor layer wherein the capacitor electrode includes the first conductor layer, second conductor layer, and third conductor layer; and
forming hemi-spherical grains on a surface of the capacitor electrode.

9. The method of fabricating a semiconductor device of claim 8, wherein:
forming the opening portion includes forming the opening portion at a position where a capacitor contact is provided.

10. The method of fabricating a semiconductor device of claim 8, wherein:
the first conductor layer has a first concentration of a first impurity that is lower than a second concentration of the first impurity in the second conductor layer; and
a third concentration of the first impurity in the third conductor layer is lower than the first concentration of the first impurity in the second conductor layer.

11. The method of fabricating a semiconductor device of claim 10, wherein:
the first concentration of the first impurity in the first conductor layer is essentially equal to the third concentration of the first impurity in the third conductor layer.

12. The method of fabricating a semiconductor device of claim 8, wherein:
forming hemi-spherical grains on the surface of the capacitor electrode includes a chemical vapor deposition method.

13. The method of fabricating a semiconductor device of claim 8, wherein:
the capacitor electrode is cylindrical having an inner surface and an outer surface; and
the hemi-spherical grains formed on the inner surface are larger than the hemi-spherical grains formed on the outer surface.

14. A semiconductor device, comprising:
a capacitor electrode including a first external conductor layer, a central conductor layer, and a second external conductor layer wherein first grain structures formed on the first external conductor layer are larger than second grain structures formed on the second external conductor layer.

15. The semiconductor device of claim 14, wherein:
a central conductor concentration of a first impurity in the central conductor layer is higher than a first external conductor concentration of the first impurity in the first external conductor layer.

16. The semiconductor device of claim 14, wherein:
the first external conductor layer, second external conductor layer, and central conductor layer are comprised of doped poly-silicon.

17. The semiconductor device of claim 14, wherein:
the first grain structures are formed on an inner surface of the capacitor electrode; and
the second grain structures are formed on an outer surface of the capacitor electrode.

18. The semiconductor device of claim 17, wherein:
the capacitor electrode is cylindrical.

19. The semiconductor device of claim 14, wherein:
the thickness of the first external conductor layer is greater than the thickness of the second external conductor layer.

20. The semiconductor device of claim 14, wherein:
the semiconductor device is a dynamic random access memory; and
the capacitor electrode stores charge indicating a data value.
